(19) United States
(12) Patent Application Publication
(10) Pub. No.: US 2009/0243743 A1
(43) Pub. Date: Oct. 1, 2009

(54) VARACTOR BANK SWITCHING BASED ON ANTI-PARALLEL BRANCH CONFIGURATION

(75) Inventors: Marcel A. Kossel, Reichenburg (CH); Thomas E. Morf, Gross(Einsiedeln) (CH); Jonas R. Weiss, Zurich (CH)

Correspondence Address: IBM-ACC-Washington;c/o Myers Dawes Andras & Sherman, LLP, 19900 MacArthur Blvd., 11th Floor, Irvine, CA, 92612, US

(73) Assignee: International Business Machines Corporation, Armonk, NY (US)

(21) Appl. No.: 12/059,826

(22) Filed: Mar. 31, 2008

(51) Int. Cl. H03B 5/12

(52) U.S. Cl. 331/179

(57) ABSTRACT

A system and apparatus for varactor bank switching for a voltage controlled oscillator, is disclosed. Varactor bank switching involves partitioning a varactor bank switch into two anti-parallel branches, wherein each branch comprises a pass-gate circuit that is series-connected to a fixed varactor or capacitor; and maintaining an output common mode voltage of an actual oscillator signal at the varactor-side terminal of each pass-gate circuit, such that a threshold voltage of the switch transistor in the pass-gate circuit is not exceeded and the switch remains in an off-state.

### BACKGROUND OF THE INVENTION

1. Field of the Invention

The present invention relates generally to varactor bank switching, and in particular to configuration of varactor bank switches.

2. Background Information

Varactor banks are applied in LC-tank voltage controlled oscillators (VCO) to perform a coarse tuning of the oscillation frequency. LC-tank oscillators are typically used in communication systems, such as in generating high frequency oscillator signals in microwave or radio frequency apparatus. A typical LC-tank circuit includes inductors (L) and capacitors (C) configured in a circuit such that the inductors and capacitors oscillate because of current or voltage exchange between inductors and capacitors at a specified frequency. To achieve a high Cmax/Cmin-ratio, switches are used in the varactor bank, where Cmax and Cmin denote the maximum and minimum capacitance values of the varactor at e.g. a logical low and high biasing voltage. If the process technology provides varactors with an inherently high variability of the capacitance, i.e. a high Cmax/Cmin-ratio, the variable capacitors in the varactor bank can directly be driven by a control signal (i.e. logical low for Cmax and logical high for Cmin) and dedicated switches within the varactor banks are not necessary. This invention, however, assumes that the process technology available (e.g., a typical digital CMOS process for mainstream applications) does only provide varactors with a low or medium Cmax/Cmin-ratio, which requires the application of switches to maximize the overall Cmax/Cmin-ratio of the varactor bank.

If the varactor bank switches in the off-state become conductive during certain fractions of the oscillation period, the phase noise of the LC-tank VCO may significantly degrade. FIG. 1 shows a schematic of a conventional varactor bank circuit, illustrating the problem that the varactor bank switch in the off-state becomes conductive during certain fractions of the oscillation period. The varactor bank is part of a tuning capacitance. The circuit in FIG. 1 includes two MOSFET varactors M4, M5 whose diffusion-side terminals are connected to the source and drain nodes of a NMOS FET switch M1. In this configuration the source and drain potentials of M1 are floating in the on-state of the varactor bank. To prevent uncontrolled variations of the potentials at these nodes, two additional MOSFET switches M2 and M3 are connected between ground and the drain and source nodes of M1. All of the transistors M1-M3 are either turned on if the varactor bank is enabled or turned off if the varactor bank is disabled. M1 is much bigger than M2 and M3 because it has to provide a low impedance path for the oscillator signal propagating from M5 to M4 and vice versa. M2 and M3 are only used to provide a high impedance dc path such as to appropriately bias the source and drain nodes of M1.

A disadvantage of the circuit in FIG. 1 is that the switch transistor M1 can get turned on in the off-state, if the source potential becomes sufficiently negative such that Vgs of M1 is higher than the threshold voltage Vth despite the gate potential of M1 is 0V (i.e., the control signal Vctrl is 0V). This situation typically occurs in the areas around the peak values of the negative-going half-waves of the oscillation signal and the described effect increases the larger the signal swing becomes. This phenomenon occurs in both half-waves of the oscillation period because the source and drain nodes exchange their roles in this symmetrical varactor bank design with respect to the definition of the half-wave directions. During those fractions of the oscillation period where Vgs>Vth holds true, the switch transistor M1 becomes conductive despite the fact that it should remain turned off. The time intervals where M1 becomes conductive are indicated by waveforms in FIG. 1 as horizontal arrows below the actual oscillation signal curve.

The impact of these partially conductive states on the phase noise performance is shown in Table I below, which summarizes certain measured results of a VCO design in 45 nm CMOS technology that applies the varactor bank switching of FIG. 1. It is clear that the phase noise performance in the off-state of the varactor banks is worse by at least 12 dBc/Hz compared to the case where the varactor bank switches are turned on. A phase noise degradation of more than 12 dBc/Hz can be regarded as being quite significant in high-Q VCO design.

TABLE 1
Measurement results of implemented prior art circuit in a 45 nm CMOS
technology. The phase noise degradation owing to the partially
conductive switches in the off-state of the varactor banks is more than
12 dBc/Hz. Note that the first two columns refer to the additionally
implemented inductor switching, which is however not directly related
to the discussed problem of varactor bank switching.

| | | all varactors | phase noise |
|---|---|---|---|
| | | banks | at 1 MHz offset |
| low frequency | all secondary coils open | off | −114.2 dBc/Hz |
| range | | on | −121.6 dBc/Hz |
| mid frequency | outer secondary | off | −107.5 dBc/Hz |
| range | coil closed | on | −119.4 dBc/Hz |
| high frequency | outer and inner | off | −101.5 dBc/Hz |
| range | secondary coils closed | on | −119.4 dBc/Hz |

### SUMMARY OF THE INVENTION

A system and apparatus for varactor bank switching for a voltage controlled oscillator is disclosed. One embodiment involves partitioning a varactor bank switch into two anti-parallel branches, wherein each branch comprises a pass-gate circuit that is series-connected to a varactor or a fixed capacitor; and maintaining an output common mode voltage of an actual oscillator signal at the varactor-side output terminal of each pass-gate circuit, such that a threshold voltage is not exceeded and the switch remains in an off-state.

Other aspects and advantages of the present invention will become apparent from the following detailed description, which, when taken in conjunction with the drawings, illustrate by way of example the principles of the invention.

### BRIEF DESCRIPTION OF THE DRAWINGS

For a fuller understanding of the nature and advantages of the invention, as well as a preferred mode of use, reference should be made to the following detailed description read in conjunction with the accompanying drawings, in which:

FIG. 1 shows a schematic of a conventional varactor bank switch, illustrating that the varactor bank switch in the off-state becomes conductive during certain fractions of the oscillation period.

FIGS. 2a-d show equivalent circuits of an LC oscillator using a PMOS tail current source together with a varactor bank switch connected in parallel to an inductor coil, according to embodiments of the invention.

FIG. 3 shows details of a varactor bank switching topology, according to an embodiment of the invention.

FIG. 4 shows results from transistor-level simulations, illustrating the performance of a varactor bank switching topology, according to an embodiment of the invention compared to conventional designs.

FIG. 5 illustrates loss angle of a conventional varactor bank switch in complex plane.

FIGS. 6a-b show conventional varactor bank switching topology examples, and FIG. 6c shows a varactor bank switching topology according to the invention, wherein every topology has a total effective varactor capacitance of C and the silicon area consumed corresponds to an equivalent of 2×R, 4×C in FIG. 6a; 1×R, 4×C in FIG. 6b; and 2×R/2, 2×0.5C in FIG. 6c.

### DESCRIPTION OF THE PREFERRED EMBODIMENTS

The following description is made for the purpose of illustrating the general principles of the invention and is not meant to limit the inventive concepts claimed herein. Further, particular features described herein can be used in combination with other described features in each of the various possible combinations and permutations. Unless otherwise specifically defined herein, all terms are to be given their broadest possible interpretation including meanings implied from the specification as well as meanings understood by those skilled in the art and/or as defined in dictionaries, treatises, etc.

The description may disclose several preferred embodiments of varactor banks, as well as operation and/or component parts thereof. While the following description will be described in terms of varactor bank for LC-tank voltage controlled oscillators for clarity and to place the invention in context, it should be kept in mind that the teachings herein may have broad application to all types of oscillators.

The embodiments described below disclose a new system for varactor bank switching based on anti-parallel branch configuration. According to one general embodiment, varactor bank switching based on an anti-parallel branch varactor bank switch is provided that prevents the varactor bank switch from getting turned on during certain fractions of the oscillation signal period despite the varactor bank switch being in the off-state.

A preferred embodiment of a varactor bank switching according to the invention involves partitioning a varactor bank switch into two anti-parallel branches, wherein each branch comprises a pass-gate circuit that is series-connected to a varactor with inherently small tuning range (low Cmax/Cmin-ratio) or a fixed capacitor; and, maintaining an output common mode voltage of an actual oscillator signal at the varactor-side terminal of each pass-gate circuit, such that a threshold voltage of the switch transistor within the pass-gate is not exceeded and the switch remains in an off-state. The output common mode voltage of the actual oscillator signal is maintained at the drain and source nodes of the varactor bank switch (i.e., pass-gate circuit) such that the threshold voltage is not exceeded and the switch does not get turned on in its off-state. The pass-gates are not floating in between two varactors because one of their terminals is always connected to either the positive or negative output port of the LC oscillator. The anti-parallel configuration can be applied between the two ports of the LC-tank allowing a reduction of the silicon area by a factor of four in comparison to conventional varactor bank switching.

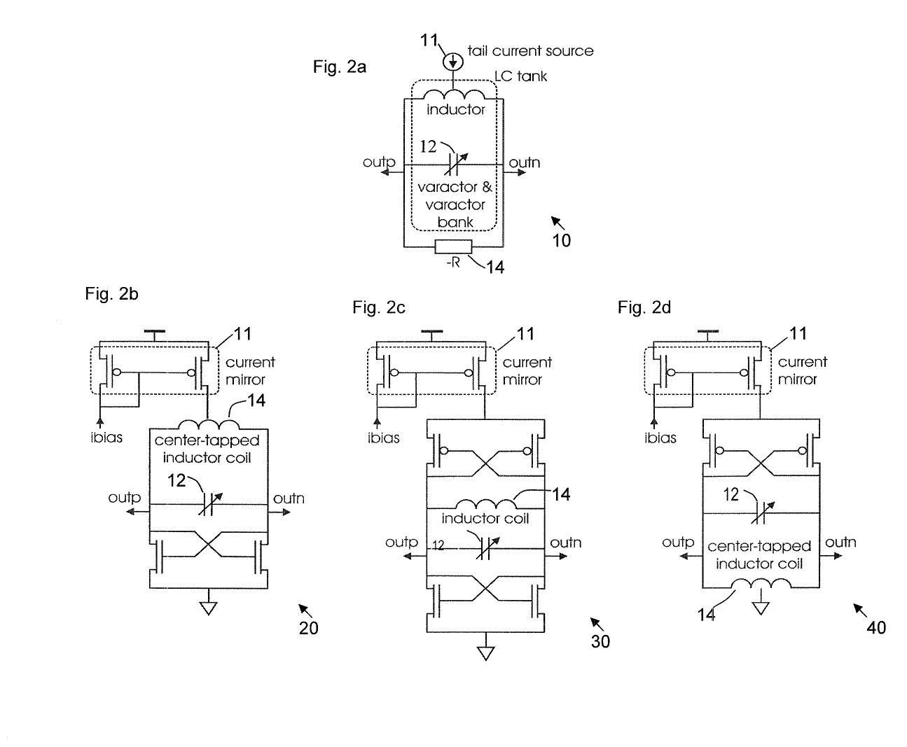

FIG. 2a shows a generic equivalent topology (i.e., circuit) of an LC VCO 10, and FIGS. 2b-2d show additional different topologies of LC VCOs 20, 30, 40, respectively, each using a PMOS tail current source 11 together with a varactor bank (e.g., tunable capacitance for coarse tuning or varactor for fine tuning) 12 according to an embodiment of the invention, connected in parallel to the inductor coil 14. Note that the fine tuning varactors are omitted in FIGS. 2b-2d and only the coarse tuning varactor banks are shown. The three topologies 20, 30 and 40, differ by the common mode voltage of the output signal. While topology 20 has a high output common mode voltage because of the center-tapped inductor coil that is connected to the tail current source, the output common mode voltage of topology 40 is low due to the ground connection of the inductor center tap. Topology 30 uses a 2-port inductor that is located in between two PMOS and NMOS cross-coupled transistor pairs and hence the output common mode voltage is in the middle of the supply voltage.

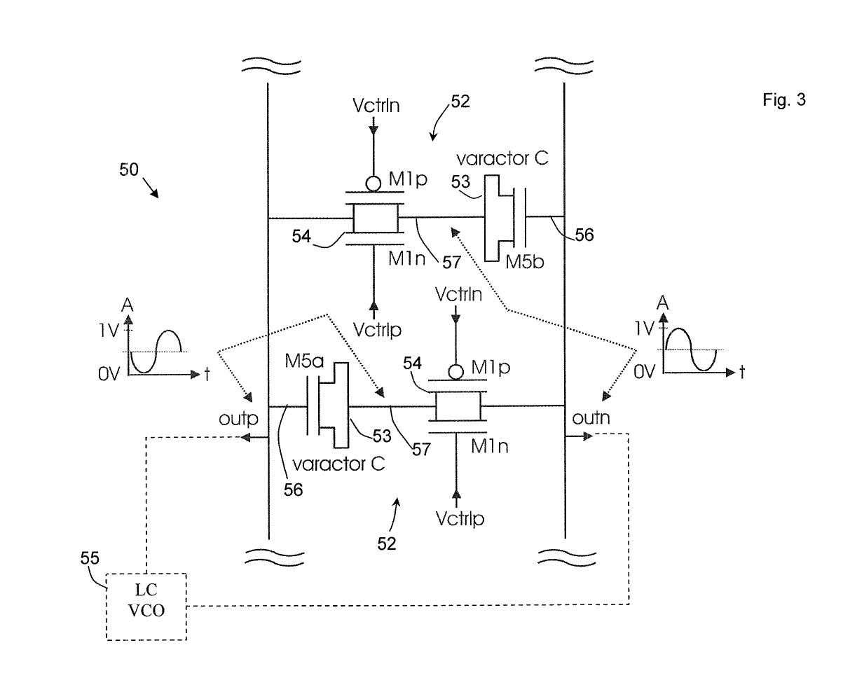

An example varactor bank switch topology according to the invention is described below, suitable for VCO topologies with a high and mid range output common mode voltage (with respect to the dc-supply voltage). FIG. 3 shows a varactor switch topology 50 implementing the varactor bank 12 according to an embodiment of the invention, for the high and mid output common mode voltages of the LC VCO. The topology 50 comprises two anti-parallel branches 52 with each branch including a varactor 53 (or a fixed capacitor) that is series connected to a pass-gate 54. Each varactor 53 is implemented by a MOSFET capacitance (i.e., M5a/M5b), and each pass-gate 54 (i.e., M1n/M1p) acts as varactor bank switch (the term “bank” in the expression “varactor bank” refers to the fact that in a LC VCO many scaled versions of such varactor banks can be operated in parallel to the actual LC-tank, and in the physical layout these circuits resemble arrays or banks). Note that only MOSFET capacitances are available as varactors in typical digital CMOS processes. In other technologies such as e.g., BICMOS, SiGe or other bipolar-like processes, diode p/n-junctions can also be used alternatively for varactors.

The pass-gates 54 are not floating in between the two varactors 53 because one terminal 56 of each pass-gate 54 is always connected to either the positive output port (outp) or the negative output port (outn) of a LC VCO 55. Thus, there is no necessity for a biasing network at the varactor-side terminal 57 of each pass-gate 54 in order to assure that the potential of the varactor's diffusion node terminal may assume appropriate voltage levels at the beginning of the on-state of the pass-gate 54. Not requiring a dedicated biasing network is advantageous.

A pass-gate is used instead of a single transistor switch in order to ensure that the varactor bank remains turned on during the positive-going half-waves of the LC VCO signals. In the off-state, the potential of the varactor-side terminal of each pass-gate follows the corresponding oscillator output signal minus a small voltage shift Vshift that is due to the finite resistance of the pass-gates in the off-state. For each pass-gate, as long as inequality relation (1) below holds true,

Vgs,M1n(t)=Vctrlp−(Vcm−Vshift−Vswing/2·sin (2πf_{osc}t))<Vth, m1n (1)

then the NFET M1n of the pass-gate does not turn on and remains in the off-state as desired. In the inequality (1) above, Vctrlp denotes a digital control signal (either 0V or 1V), Vcm denotes the output common mode voltage, Vswing denotes the signal swing, 2πf_{osc}t denotes the instantaneous phase of the oscillation and Vth,M1 denotes a threshold voltage of the transistor M1n. Note that the PFET M1p is not affected by the discussed problem of becoming conductive in its off-state because the oscillation signal cannot exceed the dc-supply voltage and the gate-source voltage of M1p remains below the threshold voltage of M1p in the off-state.

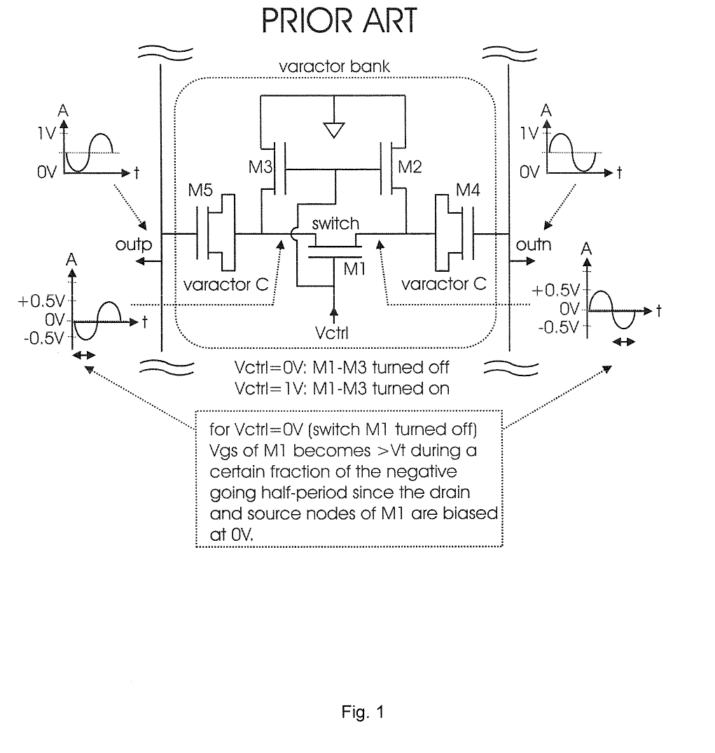

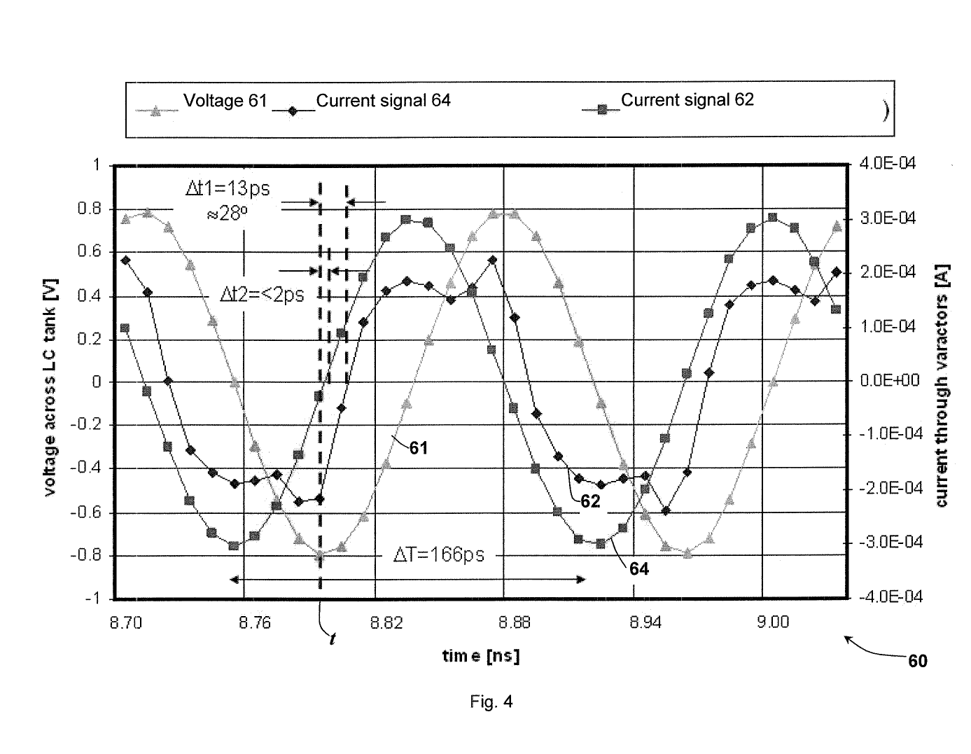

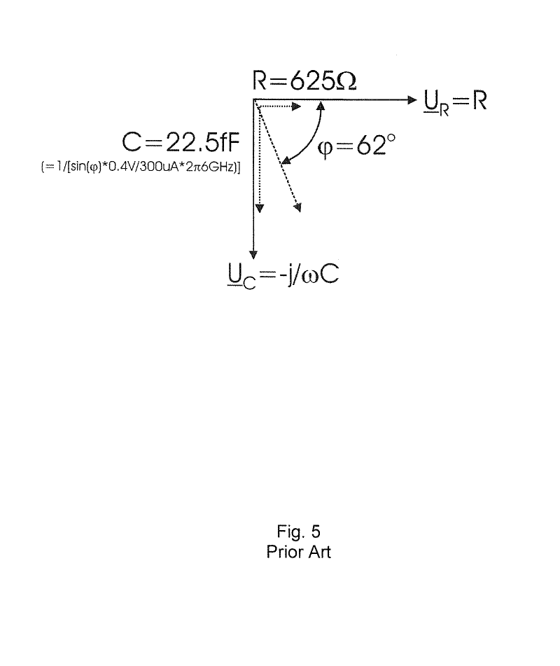

FIG. 4 shows results from example transistor-level simulations 60 illustrating the current signal performance (current through each varactor) 64 of a varactor bank switch implementing anti-parallel branch configuration, according to an embodiment of the invention (e.g., FIG. 3), compared to current signal performance 62 of a conventional design (FIG. 1). The voltage signal 61 across the varactor bank is also shown. The varactor bank switch implementing anti-parallel branch topology is advantageous since the loss angle of the current signal waveform 64 at time t (off-state) is negligible (Δt2<2 ps) indicating reduction/elimination of current leakage through the varactors, whereas the current signal waveform 62 at time t has a loss angle amounting to 28° (Δt1=13 ps) indicating significant current leakage through the varactors, and further the current waveform 62 is distorted. Both effects can be explained by the fact that, in contrast to the invention, the conventional varactor switches in the off-state become conductive in the area around the peak values of two half-waves within the oscillation period ΔT where the distortions are strongest (see FIG. 1). The distortions may generate intermodulation products that degrade the phase noise performance in addition to the impact of the non-zero loss angle. Referring to FIG. 5, an example phase angle of the conventional switches in the complex plane for the loss angle of 28° corresponds to a resistance of 625Ω and a reactance of ½π·6 GHz·22.5 fF=1.18 kΩ. This example is taken from a varactor design in 32 nm CMOS technology with length=160 nm, finger width=4.55 um and number of fingers: 24.

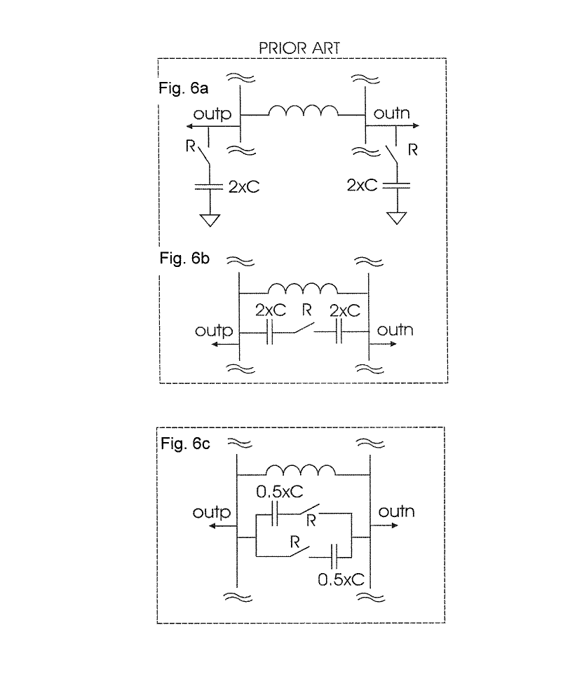

The invention improves the varactor bank switching in such a way that the phase noise degradation of conventional designs (FIG. 1) caused by the undesired conductive states of the varactor bank switches is reduced/eliminated. In addition to the reduced/eliminated current leakage through the varactors in the off-state, a varactor bank switch according to the invention reduces required silicon area for the switch topology because less silicon area is required to obtain the same capacitance value in the varactor bank. FIGS. 6a-6b show a comparison of conventional varactor bank switching topologies to a varactor bank switching topology according to the invention in FIG. 6c, in terms of switch resistances and required varactor capacitances. All of the illustrated circuits have in common that their equivalent varactor capacitance is 1×C. The term C is an arbitrary capacitance unit.

To achieve this equivalent varactor capacitance, the conventional circuit of FIG. 6a needs in total a silicon area equivalent to 4×C and additionally it has two series-connected switch resistors R. Ideally the number of switch resistors needs to be minimal in order to reduce the phase noise contribution of the LC tank. Note that R is not a dedicated device but an inevitable parasitic of the varactor switch in the on-state. In the conventional circuit shown in FIG. 6b, the same amount of silicon area for the varactors is needed (4×C), but the number of switch resistors reduces to 1×. Finally in the example topology in FIG. 6c according to the invention, a four-times smaller silicon area is required to achieve the same equivalent varactor capacitance. This is because the two varactor bank branches are connected in parallel, also the switch resistance reduces to 2×R/2.

As is known to those skilled in the art, the aforementioned example embodiments described above, according to the present invention, can be implemented in many ways, such as program instructions for execution by a processor, as software modules, as computer program product on computer readable media, as logic circuits, as silicon wafers, as integrated circuits, as application specific integrated circuits, as firmware, etc. Though the present invention has been described with reference to certain versions thereof; however, other versions are possible. Therefore, the spirit and scope of the appended claims should not be limited to the description of the preferred versions contained herein.

Those skilled in the art will appreciate that various adaptations and modifications of the just-described preferred embodiments can be configured without departing from the scope and spirit of the invention. Therefore, it is to be understood that, within the scope of the appended claims, the invention may be practiced other than as specifically described herein.

What is claimed is:

1. A method of varactor bank switching for a voltage controlled oscillator, comprising:
partitioning a varactor bank switch into two anti-parallel branches, wherein each branch comprises a pass-gate circuit that is series-connected to a fixed varactor or capacitor; and
maintaining an output common mode voltage of an actual oscillator signal at the varactor-side terminal of each pass-gate circuit, such that a threshold voltage of the switch transistor in the pass-gate circuit is not exceeded and the switch remains in an off-state.
